(19) United States
(12) Patent Application Publication
(10) Pub. No.: US 2024/0113266 A1
(43) Pub. Date: Apr. 4, 2024

(54) DISPLAY DEVICE

(71) Applicant: KYOCERA Corporation, Kyoto-shi, Kyoto (JP)

(72) Inventor: Masaya TAMAKI, Yokohama-shi, Kanagawa (JP)

(21) Appl. No.: 18/553,832

(22) PCT Filed: Apr. 4, 2022
(86) PCT No.: PCT/JP2022/017039

§ 371 Date: Oct. 3, 2023

(30) Foreign Application Priority Data
Apr. 9, 2021 (JP) 2021-066797

(51) Int. Cl. H01L 33/58; H01L 25/075

(52) U.S. Cl. CPC H01L 33/58; H01L 25/0753

(57) ABSTRACT

A display device includes a cavity member including a display surface and a plurality of cavities in the display surface, and a plurality of light emitters each located in a corresponding cavity of the plurality of cavities. When each of the plurality of light emitters has a displacement ΔPn of a reference position from a predetermined arrangement position on a bottom surface of the corresponding cavity of the plurality of cavities, where n is an integer greater than or equal to 2 and ΔPn is a scalar quantity, the displacement ΔPn has an average less than or equal to a predetermined value.

### TECHNICAL FIELD

The present disclosure relates to a display device including self-luminous light emitters such as micro-light-emitting diodes (LEDs).

### BACKGROUND OF INVENTION

A known display device is described in, for example, Patent Literature 1.

### CITATION LIST

### Patent Literature

Patent Literature 1: Japanese Unexamined Patent Application Publication No. 2018-170339

### SUMMARY

In an aspect of the present disclosure, a display device includes a cavity member including a display surface and a plurality of cavities in the display surface, and a plurality of light emitters each located in a corresponding cavity of the plurality of cavities. When each of the plurality of light emitters has a displacement ΔPn of a reference position P2 from a predetermined arrangement position P1 on a bottom surface of the corresponding cavity of the plurality of cavities, where n is an integer greater than or equal to 2 and ΔPn is a scalar quantity, the displacement ΔPn has an average less than or equal to a predetermined value.

In another aspect of the present disclosure, a display device includes a cavity member including a display surface and a plurality of cavities in the display surface, and a plurality of light emitters each located in a corresponding cavity of the plurality of cavities. When each of the plurality of light emitters has a displacement ΔPn of a reference position P2 from a predetermined arrangement position P1 on a bottom surface of a corresponding cavity of the plurality of cavities, where P1 is an origin in an orthogonal xy coordinate system and n is an integer greater than or equal to 2, and the displacement ΔPn is divided into a first displacement ΔPnx and a second displacement ΔPny, where ΔPnx and ΔPny are vector quantities, the first displacement ΔPnx is a displacement of the reference position P2 in x-direction from the predetermined arrangement position P1, and the second displacement ΔPny is a displacement of the reference position P2 in y-direction from the predetermined arrangement position P1, the first displacement ΔPnx has an average with an absolute value less than or equal to a first predetermined value W1, and the second displacement ΔPny has an average with an absolute value less than or equal to a second predetermined value W2.

### BRIEF DESCRIPTION OF THE DRAWINGS

The objects, features, and advantages of the present invention will become more apparent from the following detailed description and the drawings.

FIG. 1A is a schematic plan view of multiple light emitters arranged in a display device according to one embodiment of the present disclosure.

FIG. 1B is a schematic plan view of one of the light emitters illustrated in FIG. 1.

FIG. 2 is a schematic plan view of light emitters arranged in a display device according to another embodiment of the present disclosure.

FIG. 3A is a schematic plan view of light emitters arranged in a display device according to another embodiment of the present disclosure.

FIG. 3B is a schematic plan view of the light emitters arranged in the display device in FIG. 3A.

FIG. 4 is a schematic plan view of a light emitter arranged in a display device according to one embodiment of the present disclosure.

FIG. 5 is a schematic plan view of the light emitter in FIG. 4 arranged in a cavity.

FIG. 6 is a schematic exploded cross-sectional view of a cavity member.

FIG. 7 is a schematic cross-sectional view of the cavity member being assembled.

FIG. 8 is a plan view of the cavity member in FIG. 7 as viewed from above.

FIG. 9 is a plan view of a first substrate attached to, without displacement of edges, a second substrate having through-holes aligned with reference points corresponding to a design pixel pitch.

FIG. 10 is a plan view of the first substrate and the second substrate having through-holes being attached to each other with displacement of edges.

FIG. 11 is a plan view of the first substrate having the centers of the light emitters aligned with intersections.

FIG. 12 is a plan view of the first substrate in FIG. 11 and the second substrate having through-holes with their centers displaced from reference points corresponding to a design pixel pitch and being attached to each other without displacement of edges.

FIG. 13 is a plan view of the first substrate in FIG. 11 and the second substrate having through-holes with their centers displaced from reference points corresponding to a design pixel pitch and being attached to each other with displacement of edges.

FIG. 14 is a plan view of the first substrate in FIG. 12 and the second substrate having through-holes with their centers displaced from reference points corresponding to a design pixel pitch and being attached to each other with displacement of edges.

FIG. 15 is a schematic plan view of one light emitter arranged in a display device according to another embodiment of the present disclosure.

FIG. 16 is a schematic plan view of one light emitter arranged in a display device according to another embodiment of the present disclosure.

FIG. 17 is a schematic plan view of two light emitters arranged in a display device according to another embodiment of the present disclosure.

FIG. 18 is a schematic plan view of light emitters arranged in a display device according to another embodiment of the present disclosure.

FIG. 19 is a schematic plan view of light emitters arranged in a display device according to another embodiment of the present disclosure.

### DESCRIPTION OF EMBODIMENTS

The structure that forms the basis of a display device according to one or more embodiments of the present disclosure will now be described. A display device with the structure that forms the basis of the display device according to one or more embodiments of the present disclosure includes, for example, multiple light emitters on a substrate with several hundred thousand to several million pixels (subpixels) as described in Patent Literature 1. Such a display device is described in, for example, Patent Literature 1. The display device described in Patent Literature 1 includes multiple types of light emitters having different wavelengths. The light emitters are positioned on the substrate by placing an alignment fixture with openings on the substrate and placing the light emitters in the openings of the alignment fixture.

The known technique described in Patent Literature 1 may cause displacement of the light emitters positioned on the substrate, degrade the viewing angle characteristics of the display device, or cause variations in light intensity characteristics. Placing the alignment fixture to accurately position the light emitters on the substrate is complicated. Thus, display devices are to have high display quality without deteriorating viewing angle characteristics and light intensity characteristics when the light emitters are displaced.

A display device according to one or more embodiments of the present disclosure will now be described with reference to the accompanying drawings.

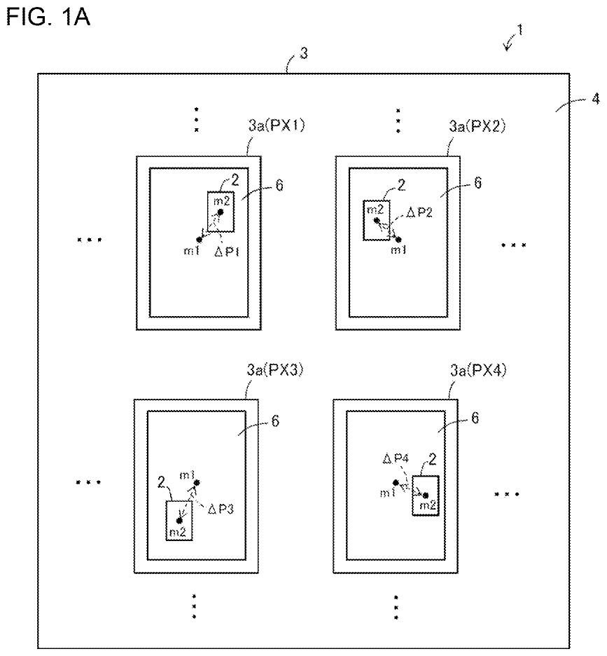

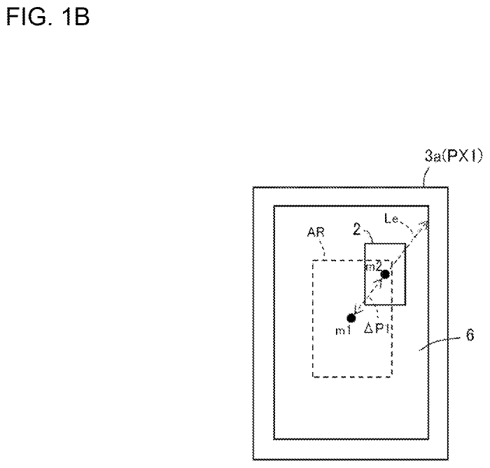

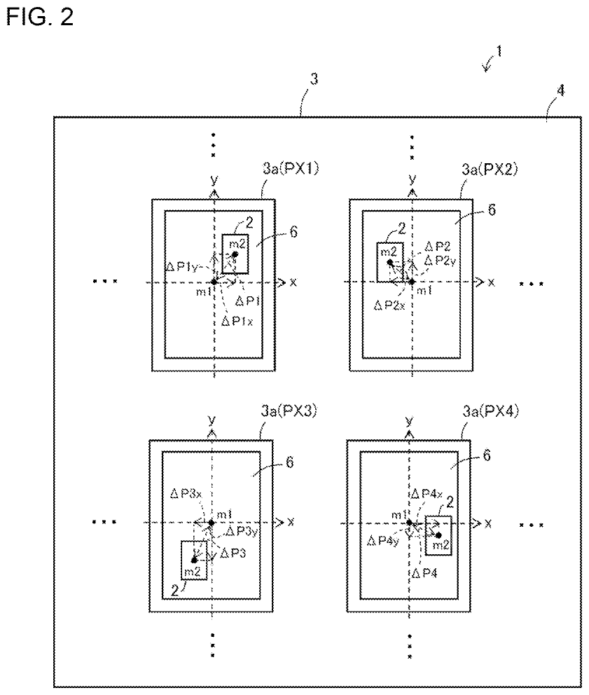

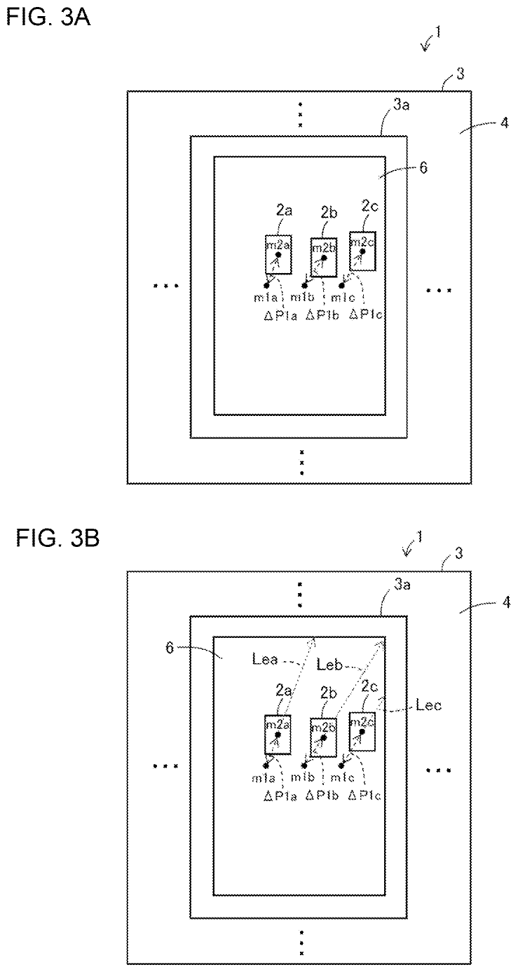

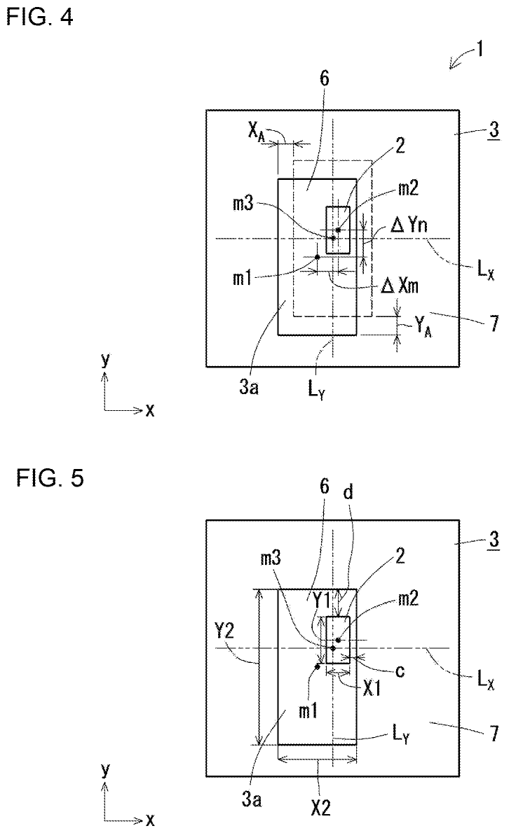

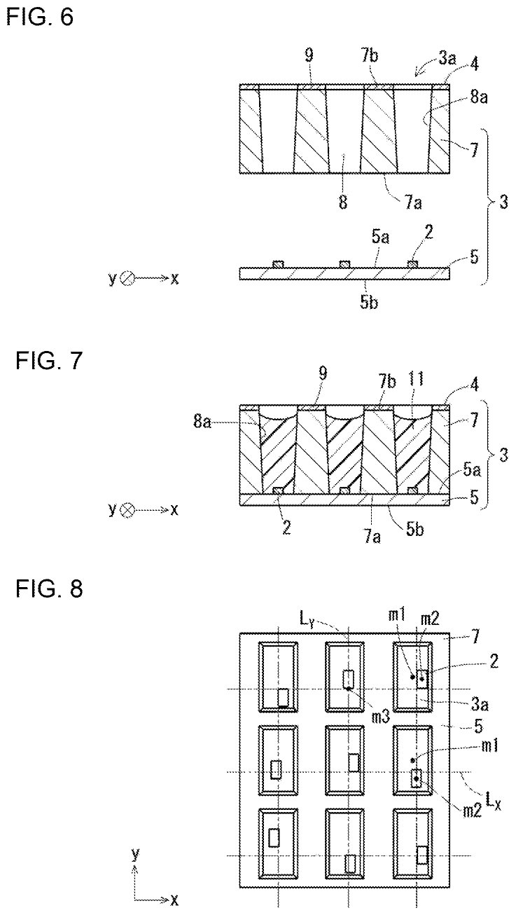

FIG. 1A is a schematic plan view of light emitters 2 arranged in a display device 1 according to one embodiment of the present disclosure. FIG. 1B is a schematic plan view of one of the light emitters 2 illustrated in FIG. 1. FIG. 2 is a schematic plan view of light emitters 2 arranged in a display device 1 according to another embodiment of the present disclosure. FIG. 3A is a schematic plan view of light emitters 2 arranged in a display device 1 according to another embodiment of the present disclosure. FIG. 3B is a schematic plan view of the light emitters 2 arranged in the display device 1 in FIG. 3A. FIG. 4 is a schematic plan view of a light emitter 2 arranged in a display device 1 according to one embodiment of the present disclosure. FIG. 5 is a schematic plan view of the light emitter 2 in FIG. 4 arranged in a cavity 3a. FIG. 6 is a schematic exploded cross-sectional view of a cavity member 3. FIG. 7 is a schematic cross-sectional view of the cavity member 3 being assembled. FIG. 8 is a plan view of the cavity member 3 in FIG. 7 as viewed from above. FIGS. 4 and 5 are enlarged views of one of multiple cavities 3a.

A reference line LX in FIG. 4 extends imaginarily on a first substrate 5 and is a design reference line in a first direction X corresponding to a pixel pitch in a column direction. An imaginary line LY extends imaginarily on the first substrate 5 and is a design reference line in a second direction Y corresponding to the pixel pitch in a row direction. An intersection m3 of the reference lines LX and LY is, for example, a design reference point to be aligned with a center point m2 of each light emitter 2 and assigned based on the predetermined pixel pitch. The intersection m3 may be a reference point to be aligned with the center of a terminal on a second substrate 7 connected to an electrode in each light emitter 2.

In one or more embodiments of the present disclosure, the display device 1 includes, as illustrated in FIG. 1A, the cavity member 3 including a display surface 4 and the cavities 3a in the display surface 4, and the light emitters 2 each located in the corresponding cavity 3a. When each light emitter 2 has a displacement ΔPn of a reference position P2 (e.g., P2 is the center point m2 of the light emitter 2) from a predetermined arrangement position P1 (e.g., P1 is a center point m1 of a bottom surface 6) on the bottom surface 6 of the cavity 3a (n is an integer greater than or equal to 2, and ΔPn is a scalar quantity), the average of displacements ΔPn is less than or equal to a predetermined value. This structure produces the effects described below. When the light emitter 2 located in each cavity 3a is displaced from the predetermined arrangement position P1 (m1) on the bottom surface 6 of the cavity 3a, the average of displacements ΔPn is less than or equal to the predetermined value. The cavities 3a (pixels), when viewed collectively, can reduce deterioration of the viewing angle characteristics and the light intensity characteristics.

The predetermined arrangement position P1 on the bottom surface 6 of the cavity 3a may be or may not be the center point m1 on the bottom surface 6. For example, when the shape of the bottom surface 6 is symmetrical, such as a circle or a square, the predetermined arrangement position P1 may be the geometric center point m1 on the bottom surface 6 (e.g., the center of a circle, or an intersection of diagonals). When the shape of the bottom surface 6 is asymmetrical, such as a triangle or a pentagon, the predetermined arrangement position P1 may be the center of gravity of the bottom surface 6. The predetermined arrangement position P1 may be slightly displaced from the center point m1 on the bottom surface 6. For example, when the reference position P2 for positioning the light emitter 2 is on a corner or an edge of the light emitter 2 that is rectangular, the predetermined arrangement position P1 may be at the corresponding position on the bottom surface 6. The reference position P2 of the light emitter 2 may be or may not be the center point m2 of the light emitter 2. For example, the reference position P2 of the light emitter 2 may be on a corner or an edge of the light emitter 2 that is rectangular.

As illustrated in FIG. 15, the bottom surface 6 may be circular and the predetermined arrangement position P1 may be at the center point m1 on the bottom surface 6. The reference position P2 may be at the center point m2 of the light emitter 2. In this case, the distance to the edge of the bottom surface 6 in the direction of displacement is the same independently of the displacement direction of the light emitter 2. In other words, the allowable range of displacement of the light emitter 2 is isotropic without being biased by direction. The bottom surface 6 may be oval. This structure has the same or similar effects as the structure described above. When the light emitter 2 is displaced in the column direction, the bottom surface 6 may be oval with the major axis extending in the column direction. When the light emitter 2 is displaced in the row direction, the bottom surface 6 may be oval with the major axis extending in the row direction.

In the embodiment described below, the predetermined arrangement position P1 on the bottom surface 6 of the cavity 3a is the center point m1 on the bottom surface 6. The reference position P2 of the light emitter 2 is the center point m2 of the light emitter 2. A cavity is a recess with an inner peripheral surface and a bottom surface. A cavity may also be referred to as a recess but will be referred to as a cavity below.

As illustrated in FIG. 1B, the displacement ΔPn may be less than or equal to a half (½) of a distance Le from the center point m1 on the bottom surface 6 as the predetermined arrangement position P1 to the edge of the bottom surface 6 of the cavity 3a. The cavity 3a allows light emitted from the light emitter 2 to converge effectively. When the displacement ΔPn exceeds a half of the distance Le, light emitted from the light emitter 2 is less likely to converge through the cavity 3a. The distance Le is the distance in a direction from the center point m1 to the center point m2. An area AR illustrated in FIG. 1B is an area on the bottom surface 6 with the displacement ΔP1 less than or equal to a half of the distance Le from the center point m1 on the bottom surface 6 to the edge of the bottom surface 6 of the cavity 3a.

The average of displacements ΔPn may be less than or equal to the predetermined value. The predetermined value may be less than or equal to ⅕ of the distance Le from the center point m1 on the bottom surface to the edge of the bottom surface 6 of the cavity 3a. The multiple pixels (cavities 3a), when viewed collectively, can further reduce deterioration of the viewing angle characteristics and the light intensity characteristics. For example, the average of displacements ΔPn is (ΣΔPn)/n=(ΔPn1+ΔPn2+ΔPn3+ΔPn4)/4 in FIG. 1A.

The cavities 3a include two cavities 3aa and 3ab that are adjacent to each other as illustrated in FIG. 17. A first direction D1, which is a direction of displacement of the light emitter 2 located in the cavity 3aa, and a second direction D2, which is a direction of displacement of the light emitter 2 located in the other cavity 3ab, may be substantially opposite to each other. In this structure, the displacements of these two light emitters 2 can be offset substantially. The two cavities 3aa and 3ab, when viewed collectively, can reduce deterioration of the viewing angle characteristics and the light intensity characteristics.

The angle between the first direction D1 and the second direction D2 may be greater than 90° and less than or equal to 180°. When the angle is less than or equal to 90°, the displacements of the two light emitters 2 are not offset. The angle between the first direction D1 and the second direction D2 may be 135 to 180° inclusive or 150 to 180° inclusive to effectively offset the displacements of the two light emitters 2.

As illustrated in FIG. 15, the two cavities 3aa and 3ab may be adjacent to each other in the row direction, in the column direction, or in the diagonal direction.

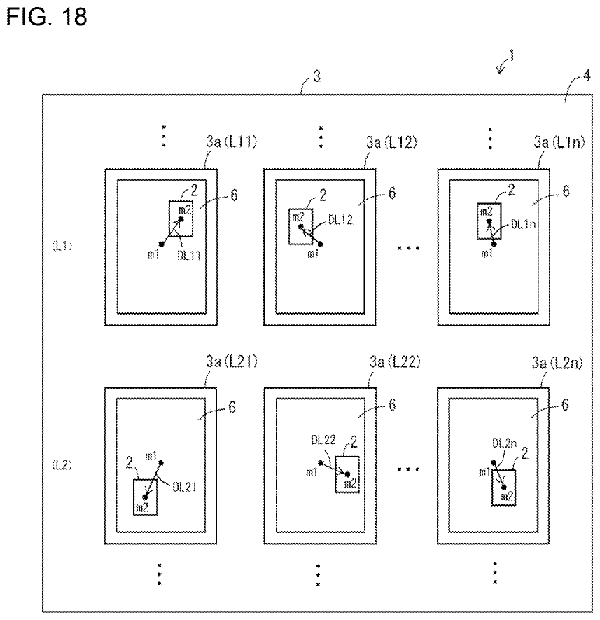

As illustrated in FIG. 18, the cavities 3a are in a matrix. The average direction of the displacements of the light emitters 2 located in the cavities 3a (L11) to 3a (Lln) (n is an integer greater than or equal to 2) in one row L1 is a first row average direction. The average direction of the displacements of the light emitters 2 located in the cavities 3a (L21) to 3a (L2n) in another row L2 adjacent to the row L1 is a second row average direction. The first row average direction and the second row average direction may be substantially opposite to each other. In this structure, the displacements of the light emitters 2 in the two rows L1 and L2 can be offset substantially. The cavities 3a in the two rows L1 and L2, when viewed collectively, can reduce deterioration of the viewing angle characteristics and the light intensity characteristics.

The first row average direction may be represented by a vector that is a composite of the vectors in the first direction DL11 to the n-th direction DLln in the row Ll. The second row average direction may be represented by a vector that is a composite of the vectors in the first direction DL21 to the n-th direction DL2n in the row L2.

All the rows of the cavities 3a in a matrix may have the above structure. More specifically, the first row and the second row may have the above structure, the second row and the third row may have the above structure, and the above structure may continue to the last row. This structure can reduce, across the entire display surface 4, deterioration of the viewing angle characteristics and the light intensity characteristics.

The angle between the first row average direction and the second row average direction may be greater than 90° and less than or equal to 180°. When the angle is less than or equal to 90°, the displacements of the light emitters 2 in the two rows collectively may not easily be offset. The angle between the first row average direction and the second row average direction may be 135 to 180° inclusive or 150 to 180° inclusive to effectively offset the displacements of the light emitters 2 in the two rows.

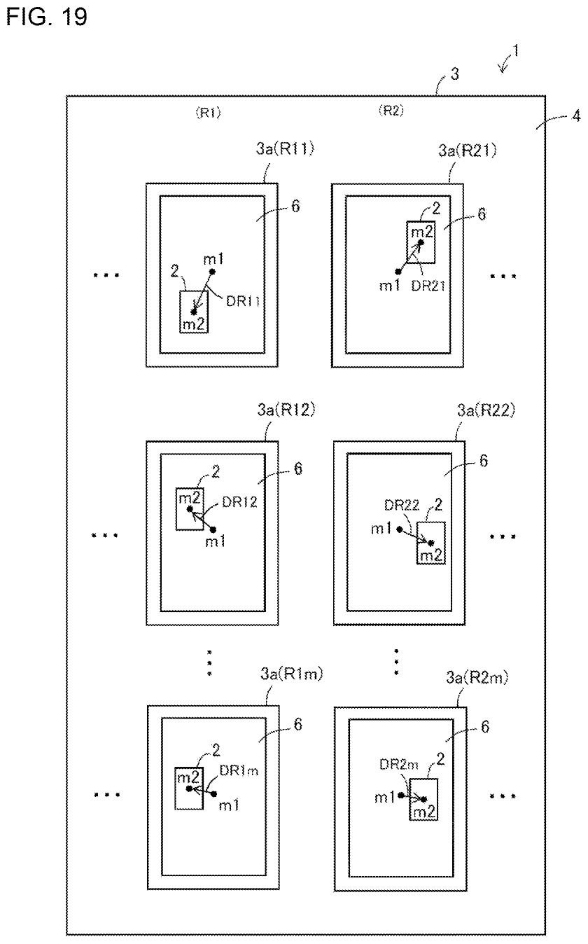

As illustrated in FIG. 19, the cavities 3a are in a matrix. The average direction of the displacements of the light emitters 2 located in the cavities 3a (R11) to 3a (R1m) (m is an integer greater than or equal to 2) in one column R1 is a first column average direction. The average direction of the displacements of the light emitters 2 located in the cavities 3a (R21) to 3a (R2m) in another column R2 adjacent to the column R1 is a second column average direction. The first column average direction and the second column average direction may be substantially opposite to each other. In this structure, the displacements of the light emitters 2 in the two columns R1 and R2 can be offset substantially. The cavities 3a in the two columns R1 and R2, when viewed collectively, can reduce deterioration of the viewing angle characteristics and the light intensity characteristics.

The first column average direction may be represented by a vector that is a composite of the vectors in the first direction DR11 to the m-th direction DR1m in the column R1. The second column average direction may be represented by a vector that is a composite of the vectors in the first direction DR21 to the m-th direction DR2m in the column R2.

All the columns of the cavities 3a in a matrix may have the above structure. More specifically, the first column and the second column may have the above structure, and the second column and the third column may have the above structure, and the above structure may continue to the last column. This structure can reduce, across the entire display surface 4, deterioration of the viewing angle characteristics and the light intensity characteristics.

The angle between the first column average direction and the second column average direction may be greater than 90° and less than or equal to 180°. When the angle is less than or equal to 90°, the displacements of the light emitters 2 in the two columns collectively may not easily be offset. The angle between the first column average direction and the second column average direction may be 135 to 180° inclusive or 150 to 180° inclusive to effectively offset the displacements of the light emitters 2 in the two columns.

The cavities 3a in a matrix may have the first row average direction substantially opposite to the second row average direction or the first column average direction substantially opposite to the second column average direction in the rows or columns in a half or more of the area of the display surface 4. This structure can further reduce, across the entire display surface 4, deterioration of the viewing angle characteristics and the light intensity characteristics.

The cavities 3a in a matrix may have the first row average direction substantially opposite to the second row average direction or the first column average direction substantially opposite to the second column average direction in all the rows or columns of the display surface 4. This structure can further reduce, across the entire display surface 4, deterioration of the viewing angle characteristics and the light intensity characteristics.

In one or more embodiments of the present disclosure, the display device 1 includes, as illustrated in FIG. 2, the cavity member 3 including the display surface 4 and the cavities 3a in the display surface 4, and the light emitters 2 each located in the corresponding cavity 3a. When each light emitter 2 has the displacement ΔPn (n is an integer greater than or equal to 2) of the reference position P2 (center point m2) from the predetermined arrangement position P1 (P1 is the origin in an orthogonal xy coordinate system and the center point m1 on the bottom surface 6) on the bottom surface 6 of the cavity 3a, and the displacement ΔPn is divided into a first displacement ΔPnx (ΔPnx is a vector quantity) and a second displacement ΔPny (ΔPny is a vector quantity), where the first displacement ΔPnx is a displacement of the center point m2 in x-direction from the center point m1, and the second displacement ΔPny is a displacement of the center point m2 in y-direction from the center point m1, the first displacements ΔPnx have an average with an absolute value less than or equal to a first predetermined value W1, and the second displacements ΔPny have an average with an absolute value less than or equal to a second predetermined value W2. This structure produces the effects described below. The displacements of the light emitters 2, when viewed collectively, can be offset substantially. The cavities 3a, when viewed collectively, can further reduce deterioration of the viewing angle characteristics and the light intensity characteristics.

The first displacement ΔPnx and the second displacement ΔPny are vector quantities and thus can be a negative value, 0, or a positive value. As illustrated in FIG. 2, a first displacement ΔP1x and a second displacement ΔP1y of the light emitter 2 in a pixel PX1 and a first displacement ΔP3x and a second displacement ΔP3y of the light emitter 2 in a pixel PX3 are opposite in the sign, and the displacements of the light emitters 2 are offset substantially. A first displacement ΔP2x and a second displacement ΔP2y of the light emitter 2 in a pixel PX2 and a first displacement ΔP4x and a second displacement ΔP4y of the light emitter 2 in a pixel PX4 are opposite in the sign, and the displacements of the light emitters 2 are offset substantially.

For example, the light emitters 2 can be arranged as described below. The light emitters 2 in the pixel PX1 and the pixel PX2 in the upper row may be located collectively above the x-axis. The light emitters 2 in the pixel PX3 and the pixel PX4 in the lower row may be located collectively below the x-axis. In other words, the light emitters 2 at least in the same row may be displaced together. The light emitters 2 in the upper half area of the display surface 4 may be located collectively above (or below) the x-axis. The light emitters 2 in the lower half area of the display surface 4 may be located collectively below (or above) the x-axis.

The light emitters 2 in the pixel PX1 and the pixel PX3 in the left column may be located collectively on the left of the y-axis. The light emitters 2 in the pixel PX2 and the pixel PX4 in the right column may be located collectively on the right of the y-axis. In other words, the light emitters 2 at least in the same column may be displaced together. The light emitters 2 in the right half area of the display surface 4 may be located collectively on the right (or left) of the y-axis. The light emitters 2 in the left half area of the display surface 4 may be located collectively on the left (or right) of the y-axis.

Light emitters 2 in one group may be located collectively at a predetermined angle θ (e.g., 45°) to the x-axis, whereas light emitters 2 in another group may be located collectively at a predetermined angle θ+180° (e.g., 225°) to the x-axis.

The first predetermined value W1 may be less than or equal to a half of the distance from the predetermined arrangement position P1 (center point m1) to the edge of the bottom surface 6 of the cavity 3a in x-direction. The second predetermined value W2 may be less than or equal to a half of the distance from the predetermined arrangement position P1 (center point m1) to the edge of the bottom surface 6 of the cavity 3a in y-direction. The displacements of the light emitters 2 can collectively be offset substantially more effectively. The cavities 3a, when viewed collectively, can further reduce deterioration of the viewing angle characteristics and the light intensity characteristics. The first predetermined value W1 may be less than or equal to ⅓, ⅕, or 1/10 of the distance from the predetermined arrangement position P1 (center point m1) to the edge of the bottom surface 6 of the cavity 3a in x-direction. The second predetermined value W2 may be less than or equal to ⅓, ⅕, or 1/10 of the distance from the predetermined arrangement position P1 (center point m1) to the edge of the bottom surface 6 of the cavity 3a in y-direction. This structure increases the above offsetting effects.

The cavity 3a may have a depth to reflect a half or more of light emitted from the light emitter 2 multiple times off an inner peripheral surface 8a (illustrated in FIG. 6). When the light emitter 2 located in the cavity 3a is displaced from the center point m1 on the bottom surface 6 of the cavity 3a, the cavity 3a with this structure can reduce deterioration of convergence of light emitted from the light emitter 2. The cavities 3a individually can thus reduce deterioration of the viewing angle characteristics and the light intensity characteristics.

Each cavity 3a may have a depth to reflect light with maximum intensity emitted from the light emitter 2 multiple times off the inner peripheral surface 8a. When the light emitter 2 located in the cavity 3a is displaced from the center point m1 on the bottom surface 6 of the cavity 3a, the cavity 3a with this structure can reduce deterioration of convergence of light emitted from the light emitter 2. The cavities 3a individually can thus reduce deterioration of the viewing angle characteristics and the light intensity characteristics. The light with maximum intensity may be emitted from the light emitter 2 in the direction at an angle with a perpendicular to the bottom surface 6 of the cavity 3a. The light with maximum intensity may be emitted from the light emitter 2 in the direction at an angle of, but not limited to, about 30 to 60° with a perpendicular to the bottom surface 6 of the cavity 3a.

Each cavity 3a may have a depth that is three times or more the height of the light emitter 2. This facilitates multiple reflections of a half or more of light emitted from the light emitter 2 off the inner peripheral surface 8a of the cavity 3a. This also facilitates multiple reflections of the light with maximum intensity emitted from the light emitter 2 off the inner peripheral surface 8a of the cavity 3a.

Each cavity 3a may include an opening in the display surface 4 that is larger than an opening in the bottom surface 6. This facilitates most of light emitted from the light emitter 2 to be emitted outside the cavity 3a. This thus further reduces deterioration of the viewing angle characteristics and the light intensity characteristics.

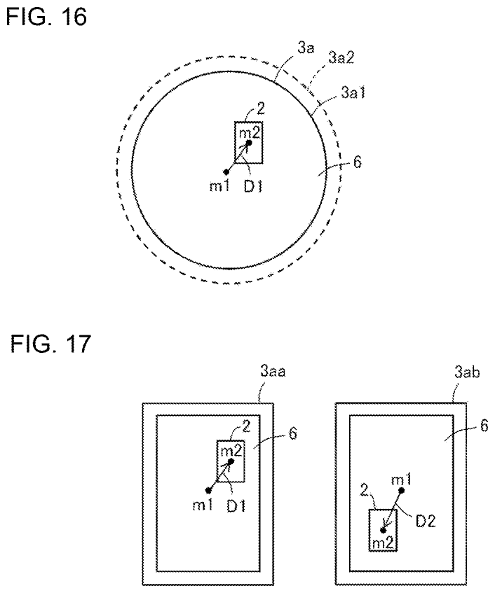

The cavity 3a may include, as illustrated in FIG. 16, an opening 3a2 in the bottom surface 6 larger than an opening 3a1 in the display surface 4. In this case, the distance from the light emitter 2 to the edge of the bottom surface 6 in the direction of displacement of the light emitter 2 tends to be longer. In other words, the allowable range of displacement of the light emitter 2 is expanded easily. The cavity 3a may be circular in a plan view. The allowable range of displacement of the light emitter 2 is isotropic without being biased by direction.

The inner peripheral surface 8a of the cavity 3a may be light-reflective. This thus further reduces deterioration of the light intensity characteristics. The side wall of the cavity 3a may be made of a metal material with high light reflectance such as aluminum. Each cavity 3a may include a light-reflective layer made of a metal material with high light reflectance such as aluminum on the inner peripheral surface 8a.

In one or more embodiments of the present disclosure, the display device 1 may include, as illustrated in FIG. 3A, the cavity member 3 including the display surface 4 and the cavities 3a in the display surface 4, and multiple light emitters 2a, 2b, and 2c located in the corresponding cavity 3a. For the light emitters 2a, 2b, and 2c, the average of displacements ΔP1a, ΔP1b, and ΔP1c (scalar quantities) may be less than or equal to a predetermined value, where ΔP1a, ΔP1b, and ΔP1c are the displacements of center points m2a, m2b, and m2c of the light emitters 2a, 2b, and 2c from predetermined arrangement positions P1a, P1b, and P1c (center points m1a, m1b, and m1c) on the bottom surface 6 of the cavity 3a. The center points m1a, m1b, and m1c are the centers of the light emitters 2a, 2b, and 2c as the arrangement reference points. When the light emitters 2a, 2b, and 2c located in the cavities 3a are displaced from the center points m1a, m1b, and m1c on the bottom surface 6 of the cavity 3a, the average of the displacements ΔP1a, ΔP1b, and ΔP1c is less than or equal to the predetermined value. The cavities 3a individually thus easily allow light emitted from the light emitters 2a, 2b, and 2c to converge. This thus reduces deterioration of the viewing angle characteristics and the light intensity characteristics.

For example, the light emitter 2a may be a red light emitter that emits red light, the light emitter 2b may be a green light emitter that emits green light, and the light emitter 2c may be a blue light emitter that emits blue light. The average of the displacements ΔP1a, ΔP1b, and ΔP1c can be expressed as (ΔP1a+ΔP1b+ΔP1c)/3.

As illustrated in FIG. 3B, the displacements ΔP1a, ΔP1b, and ΔP1c may be less than or equal to the halves of the distances Lea, Leb, and Lec from the respective center points m1a, m1b, and m1c to the edge of the bottom surface 6 of the cavity 3a. In other words, ΔP1a≤Lea/2, ΔP1b≤Leb/2, and ΔP1c≤Lec/2. The cavity 3a allows light emitted from the light emitters 2a, 2b, and 2c to converge effectively.

The average of the displacements ΔP1a, ΔP1b, and ΔP1c may be less than or equal to a predetermined value, and the predetermined value may be less than or equal to ⅕ of the distances Lea, Leb, and Lec from the respective center points m1a, m1b, and m1c to the edge of the bottom surface 6 of the cavity 3a. In other words, (ΔP1a+ΔP1b+ΔP1c)/3≤{(Lea+Leb+Lec)/3}/5. The cavity 3a allows light emitted from the light emitters 2a, 2b, and 2c to converge more effectively.

Although the structure illustrated in FIG. 3A includes the single cavity 3a containing the light emitters 2a, 2b, and 2c, the cavity member 3 may include multiple cavities 3a each containing the light emitters 2a, 2b, and 2c. Such cavities 3a may have the same or similar structure.

In one or more embodiments of the present disclosure, the display device 1 may include the center points m1a, m1b, and m1c each being the origin in the orthogonal xy coordinate system. When the displacements ΔP1a, ΔP1b, and ΔP1c are divided into first displacements ΔP1ax, ΔP1bx, and ΔP1cx (ΔP1ax, ΔP1bx, and ΔP1cx are vector quantities) of the center points m2a, m2b, and m2c in x-direction from the center points m1a, m1b, and m1c and second displacements ΔP1ay, ΔP1by, and ΔP1cy (ΔP1ay, ΔP1by, and ΔP1cy are vector quantities) of the center points m2a, m2b, and m2c in y-direction from the center points m1a, m1b, and m1c, the first displacements ΔP1ax, ΔP1bx, and ΔP1cx have an average with an absolute value less than or equal to a first predetermined value W1x, and the second displacements ΔP1ay, ΔP1by, and ΔP1cy have an average with an absolute value less than or equal to a second predetermined value W2y. The displacements of the light emitters 2a, 2b, and 2c can collectively be offset substantially. The cavities 3a individually allow light emitted from the light emitters 2a, 2b, and 2c to converge more effectively. This thus further reduces deterioration of the viewing angle characteristics and the light intensity characteristics.

Although the above structure includes the single cavity 3a containing the light emitters 2a, 2b, and 2c, the cavity member 3 may include multiple cavities 3a each containing the light emitters 2a, 2b, and 2c. Such cavities 3a may have the same or similar structure.

In the present embodiment, the display device 1 may have the structure illustrated in any of FIGS. 4 to 14. The display device 1 includes the display surface 4 facing a viewer, the cavity member 3 including the cavities 3a in the display surface 4 in a lattice with m (m is a positive integer greater than or equal to 3) columns in the first direction X and n (n is a positive integer greater than or equal to 3) rows in the second direction Y perpendicular to the first direction X, and the light emitters 2 located in the cavities 3a. In the present embodiment, the display device 1 displays actual full-color images, and includes a notably large number of pixels, for example, about 100,000 to 200,000 pixels in the first direction X and about 100,000 to 200,000 pixels in the second direction Y in a lattice as high-density pixels on the display surface 4. A structure including m columns that are three columns in the first direction X and n rows that are three rows in the second direction Y in a lattice is described below for convenience.

As illustrated in FIGS. 6 and 7, the cavity member 3 may include the first substrate 5 and the second substrate 7 attached to each other. The first substrate 5 may include the light emitters 2. The second substrate 7 may include through-holes 8 (described later) defining the cavities 3a in the same pattern as for the first substrate 5. With the first substrate 5 and the second substrate 7 attached to each other, the light emitters 2 are placed on the bottom surfaces 6 exposed and facing the openings of the cavities 3a, with light from the light emitters 2 located in the cavities 3a to be emitted from the openings of the cavities 3a.

The light emitters 2 on the first substrate 5 are located in the through-holes 8 in the second substrate 7 with the first substrate 5 and the second substrate 7 attached to each other. The second substrate 7 may be thicker than the first substrate 5. The second substrate 7 includes the through-holes 8 with the inner peripheral surfaces 8a to reflect light emitted from the light emitters 2 at least once or specifically multiple times. This allows substantially collimated light to be emitted outside from the light emitters 2 through the through-holes 8. The display surface 4 of the display device 1 thus emits light with increased directivity. To allow light emitted from the light emitters 2 to be reflected off the inner peripheral surfaces 8a of the through-holes 8 at least once or specifically multiple times, the display device 1 may have parameters determined as appropriate based on, for example, the intensity distribution of light at a position immediately before the display surface 4 after emitted from the light emitters 2. The parameters may include the thickness of the second substrate 7, the shape of each through-hole 8, and the dimensional ratio between the through-holes 8 and the light emitters 2.

The light emitters 2 may be, for example, self-luminous elements such as light-emitting diodes (LEDs), organic LEDs (OLEDs), or semiconductor laser diodes (LDs). In the present embodiment described below, the light emitters 2 are micro-LEDs. Each micro-LED may be rectangular (having a short side in the first direction X and a long side in the second direction Y in FIG. 4) in a plan view with each side having a length of about 1 to 100 μm inclusive, or about 5 to 20 μm inclusive.

When each light emitter 2 is located, in a plan view, as illustrated in FIG. 8, with a displacement ΔXm, in the first direction X, of the center point m2 (the centroid of the light emitter 2 in a plan view) of the light emitter 2 from the center point m1 (the centroid of the bottom surface 6) on the bottom surface 6 exposed in the through-hole 8 of the cavity 3a and a displacement ΔYn, in the second direction Y, of the center point m2 of the light emitter 2 from the center point m1 on the bottom surface 6 of the cavity 3a, the displacements ΔXm of the light emitters 2 in the first direction X have an average ΔXAV with an absolute value |ΔXAV| less than or equal to a first predetermined value Wx (|ΔXAV|≤Wx). The displacements ΔYn of the light emitters 2 in the second direction Y have an average ΔYAV with an absolute value |ΔYAV| less than or equal to a second predetermined value WY (|ΔYAV|≤WY).

The first predetermined value WX and the second predetermined value WY are defined using the first direction X (rightward in FIG. 4) as a positive direction and an opposite direction as a negative direction, and the second direction Y (upward in FIG. 4) as a positive direction and an opposite direction as a negative direction. The sum of the displacements ΔXm and ΔYn of the light emitters 2 in the first direction X and the second direction Y may be set to substantially 0.

In the present embodiment, the display device 1 includes the light emitters 2 randomly located in the cavities 3a to satisfy the conditions (|ΔXAV|≤Wx and |ΔYAV|≤WY). The display device 1 can thus have high display quality with reduced non-uniformity in the light emitted from the single display surface 4 and reduced deterioration of the viewing angle characteristics and the light intensity characteristics. A composite display device (multi-display) including multiple display devices 1 with side portions of adjacent display devices 1 joined together can maintain high display quality across the entire display surface. The light emitters 2 may be randomly located with, for example, about a half of the light emitters 2 displaced by the displacement ΔXm in the positive direction of the first direction X from the center point m2 on the bottom surface 6 of the cavity 3a and the remaining half of the light emitters 2 displaced by the displacement ΔXm in the negative direction of the first direction X, or about a half of the light emitters 2 displaced by the displacement ΔYn in the positive direction of the second direction Y from the center point m2 on the bottom surface 6 of the cavity 3a and the remaining half of the light emitters 2 displaced by the displacement ΔYn in the negative direction of the second direction Y from the center point m2 on the bottom surface 6 of the cavity 3a.

The first substrate 5 includes a first surface 5a and a second surface 5b opposite to the first surface 5a. The first surface 5a includes the bottom surfaces 6 of the cavities 3a with the second substrate 7 attached to the first substrate 5. The second substrate 7 includes a third surface 7a facing the first surface 5a and a fourth surface 7b opposite to the third surface 7a with the second substrate 7 attached to the first substrate 5. Each light emitter 2 is located inward from the inner peripheral surface 8a on the bottom surface 6 exposed in the through-hole 8. The light emitter 2 being a micro-LED includes an anode electrode and a cathode electrode and may be electrically and mechanically connected to an anode terminal and a cathode terminal preformed on the first surface 5a of the first substrate 5 by flip-chip connection using a conductive connector, such a solder ball, a metal bump, or a conductive adhesive. The anode electrode and the cathode electrode in the light emitter 2 may be electrically connected using a conductive connector such as a bonding wire.

The first substrate 5 may be a plate or a block, and may be, for example, triangular, square, rectangular, hexagonal, or in any other shape in a plan view. The first substrate 5 is made of, for example, a glass material, a ceramic material, a resin material, a metal material, or a semiconductor material. Examples of the glass material used for the first substrate 5 include borosilicate glass, crystallized glass, quartz, and soda glass. Examples of the ceramic material used for the first substrate 5 include alumina (Al₂O₃), aluminum nitride (AlN), silicon nitride (Si₃N₄), zirconia (ZrO₂), and silicon carbide (SiC). Examples of the resin material used for the first substrate 5 include an epoxy resin, a polyimide resin, and a polyamide resin. Examples of the metal material used for the first substrate 5 include aluminum (Al), titanium (Ti), beryllium (Be), magnesium (Mg) (specifically, high-purity magnesium with a Mg content of 99.95% or higher), zinc (Zn), tin (Sn), copper (Cu), iron (Fe), chromium (Cr), nickel (Ni), and silver (Ag). The metal material used for the first substrate 5 may be an alloy material. Examples of the alloy material used for the first substrate 5 include an iron alloy mainly containing iron (a Fe—Ni alloy, a Fe—Ni—Co (cobalt) alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the first substrate 5 include silicon (Si), germanium (Ge), and gallium arsenide (GaAs). The first substrate 5 may include a single layer of, for example, the glass material, the ceramic material, the resin material, the metal material, or the semiconductor material described above, or may be a stack of multiple layers of any of these materials. For the first substrate 5 being a stack of multiple layers, the layers may be made of the same or different materials.

The second substrate 7 may be a plate or a block, and may be, for example, triangular, square, rectangular, hexagonal, or in any other shape in a plan view. In the present embodiment, the first substrate 5 and the second substrate 7 have the same shape in a plan view. The second substrate 7 is made of, for example, a glass material, a ceramic material, a resin material, a metal material, or a semiconductor material. Examples of the glass material used for the second substrate 7 include borosilicate glass, crystallized glass, quartz, and soda glass. Examples of the ceramic material used for the second substrate 7 include alumina, aluminum nitride, silicon nitride, zirconia, and silicon carbide. Examples of the resin material used for the second substrate 7 include an epoxy resin, a polyimide resin, and a polyamide resin. Examples of the metal material used for the second substrate 7 include aluminum, titanium, beryllium, magnesium (specifically, high-purity magnesium with a Mg content of 99.95% or higher), zinc, tin, copper, iron, chromium, nickel, and silver. The metal material used for the second substrate 7 may be an alloy material. Examples of the alloy material used for the second substrate 7 include an iron alloy mainly containing iron (a Fe—Ni alloy, a Fe—Ni—Co alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the second substrate 7 include silicon, germanium, and gallium arsenide. The second substrate 7 may include a single layer of any of the above metal materials, or may be a stack of multiple layers of any of the above metal materials. For the second substrate 7 being a stack of multiple layers, the layers may be made of the same or different materials.

The through-holes 8 in the second substrate 7 may have a section parallel to the third surface 7a being, for example, square, rectangular, circular, or in any other shape. As illustrated in, for example, FIG. 8, each through-hole 8 includes an opening in the fourth surface 7b that may have an outer edge surrounding the outer edge of the bottom surface 6 of the corresponding element-mounting portion in a plan view. As illustrated in, for example, FIG. 7, each through-hole 8 may have a section parallel to the third surface 7a gradually enlarging from the third surface 7a toward the fourth surface 7b. This structure facilitates output of light emitted from the light emitters 2 outside the display surface 4 of the display device 1. The through-holes 8 may be formed by, for example, punching, electroforming (plating), cutting, or laser beam machining. For the second substrate 7 made of a metal material or an alloy material, the through-holes 8 may be formed by, for example, punching or electroforming. For the second substrate 7 made of a semiconductor material, the through-holes 8 may be formed by, for example, photolithography including dry etching.

The second substrate 7 may include the through-holes 8 with the first predetermined value WX being 0.25 to 2 times, inclusive, the width X1 of each light emitter 2 in the first direction X and the second predetermined value WY being 0.25 to 2 times, inclusive, the width Y1 of each light emitter 2 in the second direction Y. This can reduce deterioration of the viewing angle characteristics and the light intensity characteristics by, for example, determining the first predetermined value WX and the second predetermined value WY for a light emitter 2 with a certain size. The first predetermined value WX and the second predetermined value WY for a light emitter 2 with another size can be estimated easily based on the proportional relation with the first predetermined value WX and the second predetermined value WY of the size determined previously. This can improve the design convenience and improve productivity for the light emitters 2 with different sizes.

The light emitters 2 and the cavities 3a may be arranged in the manner described below based on the relationship between the center point m1 of each through-hole 8 and the center point m2 of each light emitter 2.

The displacements ΔXm and ΔYn of each light emitter 2 may be determined based on one of or a combination of a displacement of the center point m2 of the light emitter 2 from the intersection m3 of the reference lines LX and LY corresponding to the pixel pitch, a displacement of the center point m1 of the through-hole 8 from the intersection m3 of the reference lines LX and LY corresponding to the pixel pitch, and a displacement of the second substrate 7 attached to the first substrate 5 from the first substrate 5.

The displacement ΔXm of the center point m2 of each of (m×n) light emitters 2 in the first direction X from the center point m1 of the corresponding through-hole 8 may satisfy formula 1 below, where X2 is the width of the bottom surface 6 in the first direction X, and the bottom surface 6 of the cavity 3a is rectangular in a plan view.

ΔXₘ<(X1−X2)/2 (1)

The displacement ΔYn of the center point m2 of each light emitter 2 in the second direction Y from the center point m2 of the corresponding through-hole 8 may satisfy formula 2 below.

ΔYₙ<(Y1−Y2)/2 (2)
where Y2 is the width of the bottom surface 6 in the second direction Y. The light emitter 2 can avoid contact with the inner peripheral surface 8a of the through-hole 8.

The light emitters 2 and the cavities 3a may be arranged in the manner described below based on the relationship between the displacement XA in the first direction X and the displacement YA in the second direction Y of the center point m1 of each through-hole 8 from the reference point corresponding to the design pixel pitch, and the displacement ΔXm1 in the first direction X and the displacement ΔYn1 in the second direction Y of the center point m2 of each light emitter 2 from the intersection m3.

In the cavity member 3, ΔXm1 is the displacement in the first direction X of the center point m2 of each light emitter 2 from the intersection m3 of the reference lines LX and LY corresponding to the pixel pitch, ΔYn1 is the displacement in the second direction Y of the center point m2 of the light emitter 2 from the intersection m3 of the reference lines LX and LY, XA is the displacement of the through-hole 8 in the first direction X from the reference point corresponding to the design pixel pitch, YA is the displacement of the center point m1 of the through-hole 8 in the second direction Y from the reference point corresponding to the design pixel pitch, X1 is the width of the light emitter 2 in the first direction X, and Y1 is the width of the light emitter 2 in the second direction Y. In this structure, the displacement ΔXm1 of the center point m2 of the light emitter 2 in the first direction from the intersection m3 and the displacement ΔYn1 of the center point m2 of the light emitter 2 in the second direction Y from the intersection m3 may satisfy formulas 3 and 4 below. Each light emitter 2 can avoid contact with the inner peripheral surface 8a of the corresponding through-hole 8. Each light emitter 2 can be located inward from the outer edge of the bottom surface 6 of the corresponding cavity 3a.

X_{A}+ΔXm1<(X2−X1)/2 (3)

Y_{A}+ΔYn1<(Y2−Y1)/2 (4)

The depth of each cavity 3a (equivalent to the thickness of the second substrate 7 in the present embodiment) in the direction perpendicular to the display surface 4 is another factor that affects the viewing angle characteristics and the light intensity characteristics of light emitted from the display surface 4. When the width X1 of each light emitter 2 is 1 μm≤X1≤100 and the width Y1 is 1 μm≤Y1≤100 the light emitter 2 is located on the bottom surface 6 facing the opening of the corresponding cavity 3a. Each cavity 3a may have a depth to reflect light emitted from the light emitter 2 at least once or specifically multiple times off the inner peripheral surface 8a facing the internal space of the cavity 3a. The depth of the cavities 3a can be determined based on an area A1 of the opening of each cavity 3a and an area A2 of the bottom surface 6 of each cavity 3a. The ratio γ (=A1/A2) of the area A1 of the opening to the area A2 of the bottom surface 6 with respect to the thickness of the second substrate 7 is 1.5≤γ≤30. This can increase the directivity of light emitted from each light emitter 2 in the corresponding cavity 3a and reduce deterioration of the viewing angle characteristics and the light intensity characteristics. When the area of the opening in the third surface 7a and the area of the opening in the fourth surface 7b of the second substrate 7 are determined, the inclination angle of the inner peripheral surface 8a of each through-hole 8 to the normal of the third surface 7a is determined. An area ratio γ can thus be used to obtain a design reference parameter that achieves optimal viewing angle characteristics and optimal light intensity characteristics. In other words, the thickness of the second substrate 7 and the pitch of the sub-pixels can be used as indicators for determining the optimal shape of the cavities 3a and can assist in designing the cross-sectional structure.

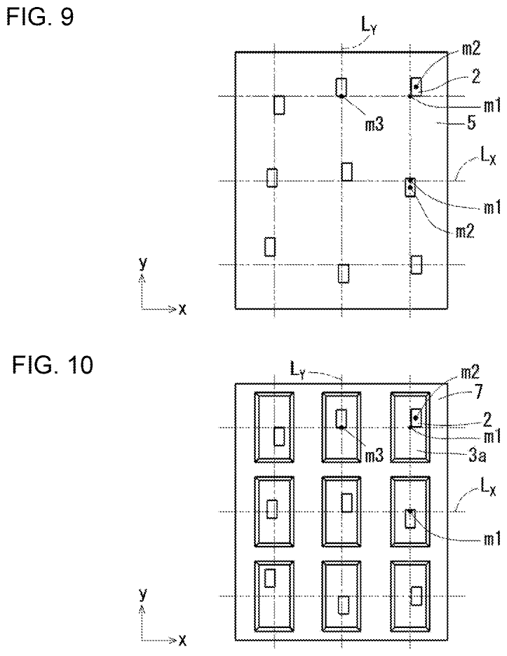

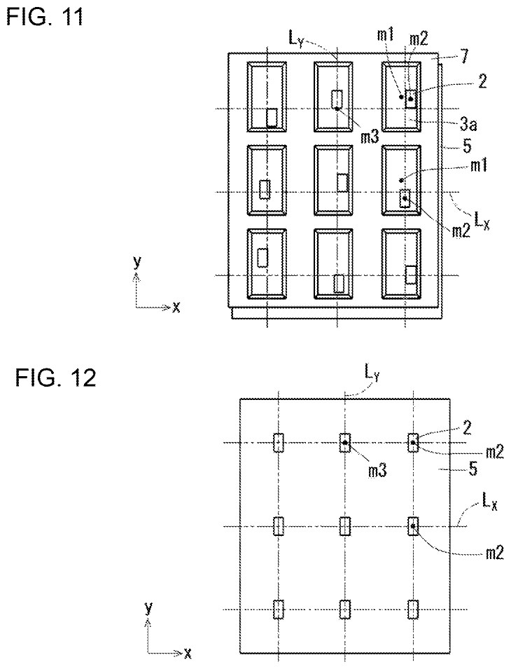

FIG. 9 is a plan view of the first substrate 5 having the center points m2 of the light emitters 2 displaced from the intersections m3. FIG. 10 is a plan view of the first substrate 5 illustrated in FIG. 9 attached to, without displacement of edges, the second substrate 7 having the through-holes 8 aligned with reference points corresponding to a design pixel pitch. FIG. 11 is a plan view of the first substrate 5 illustrated in FIG. 9 and the second substrate 7 having the through-holes 8 being attached to each other with displacement of edges. The first substrate 5 and the second substrate 7 are displaced when the first substrate 5 and the second substrate 7 are attached to each other with the edges of the first substrate 5 and the edges of the second substrate 7 having the same shape not matching in a plan view. The first substrate 5 and the second substrate 7 are not displaced when the first substrate 5 and the second substrate 7 are attached to each other with the edges of the first substrate 5 and the edges of the second substrate 7 having the same shape matching in a plan view. As illustrated in FIG. 9, each light emitter 2 is located on the first substrate 5 with the center point m2 displaced from the intersection m3 of the reference lines LX and LY corresponding to the pixel pitch. The through-holes 8 are located in the second substrate 7 in a predetermined cycle with the center point m1 of each through-hole 8 positioned at the reference point corresponding to the design pixel pitch. When the first substrate 5 and the second substrate 7 are attached to each other without their edges matching each other as illustrated in FIG. 11, the displacements ΔXm in the first direction X of the center points m2 of the light emitters 2 from the center points m1 of the through-holes 8 may have an average with an absolute value |ΔXAV| less than or equal to the first predetermined value WX, and the displacements ΔYn in the second direction Y of the center points m2 of the light emitters 2 from the center points m1 of the through-holes 8 may have an average with an absolute value |ΔYAV| less than or equal to the second predetermined value WY. In this case, the display device 1 can have high display quality with reduced deterioration of the viewing angle characteristics and the light intensity characteristics.

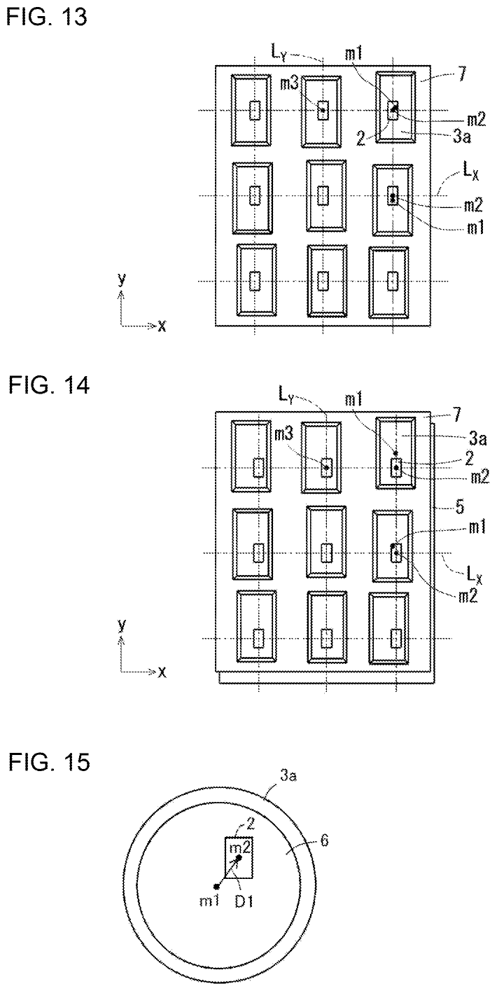

FIG. 12 is a plan view of the first substrate 5 having the center points m2 of the light emitters 2 aligned with the intersections m3. FIG. 13 is a plan view of the first substrate 5 in FIG. 12 and the second substrate 7 having the through-holes 8 with their center points m2 displaced from the reference points corresponding to a design pixel pitch and being attached to each other without displacement of edges. FIG. 14 is a plan view of the first substrate 5 in FIG. 12 and the second substrate 7 having the through-holes 8 with their center points m2 displaced from the reference points corresponding to a design pixel pitch and being attached to each other with displacement of edges. As illustrated in FIG. 12, the light emitters 2 are located without displacement as designed with their center points m2 at the intersections m3 of the reference lines LX and LY corresponding to the pixel pitch. As illustrated in FIG. 13, the second substrate 7 includes the center points m1 of the through-holes 8 displaced from the reference points corresponding to the design pixel pitch. When the first substrate 5 and the second substrate 7 are attached to each other without their edges matching each other as illustrated in FIG. 14, the displacements ΔXm in the first direction X of the center points m1 of the through-holes 8 from the center points m2 of the light emitters 2 may have an average with an absolute value |ΔXAV| less than or equal to the first predetermined value WX, and the displacements ΔYn in the second direction Y of the center points m1 of the through-holes 8 from the center points m2 of the light emitters 2 may have an average with an absolute value |ΔYAV| less than or equal to the second predetermined value WY. In this case, the display device 1 can have high display quality with reduced deterioration of the viewing angle characteristics and the light intensity characteristics.

In another embodiment, the display device 1 may further include a light-absorbing film 10 on the display surface 4. The light-absorbing film 10 may be formed by, for example, applying a photo-curing or a thermosetting resin material containing a light-absorbing material to the third surface 7a of the second substrate 7 and curing the material. The light-absorbing material may be, for example, an inorganic pigment. Examples of the inorganic pigment may include carbon pigments such as carbon black, nitride pigments such as titanium black, and metal oxide pigments such as Cr—Fe—Co, Cu—Co—Mn, Fe—Co—Mn, and Fe—Co—Ni—Cr pigments. The light-absorbing film 10 absorbs external light incident on the third surface 3b. In the display device 1 according to the present embodiment, the fourth surface 7b reduces reflection of external light. The display surface 4 thus emits image light with less interference with reflected external light. The display device 1 can have high display quality with reduced deterioration of the viewing angle characteristics and the light intensity characteristics.

The light-absorbing film 10 may include a rough surface that absorbs incident light. The light-absorbing film 10 may be, for example, a black film formed by mixing a black pigment such as carbon black in a base material such as a silicone resin. The light-absorbing film 10 may have an unevenness with an arithmetic mean roughness of about 10 to 50 μm or 20 to 30 μm formed on the surface of the black film by, for example, a transfer method. This structure greatly increases the light-absorbing effect.

In another embodiment, the display device 1 may include a light-reflective film made of a metal material such as aluminum, silver, or gold on the inner peripheral surface 8a of each through-hole 8. This light-reflective film allows light emitted from the light emitters 2 to be reflected in the through-holes 8 with an increased reflectance and reduced loss independently of, for example, the material for the second substrate 7 or the surface roughness Ra of the inner peripheral surfaces 8a. The display device thus outputs light emitted from the light emitters 2 on the display surface 4 more efficiently and displays high-intensity images.

The light-reflective film may be formed on the inner peripheral surface 8a of each through-hole 8 using a thin film formation method such as CVD, vapor deposition, or plating, or using a thick film formation method such as firing and solidifying a resin paste containing particles of, for example, aluminum, silver, or gold. The light-reflective film may be formed on the inner peripheral surface 8a of the through-hole 8 by joining a film containing, for example, aluminum, silver, gold, or an alloy of any of these metals. The light-reflective film may have a protective film on the outer surface of the light reflective film to reduce oxidation of the light reflective film, which may cause a decrease in reflectance. The light-reflective film can improve display quality by further reducing deterioration of the viewing angle characteristics and the light intensity characteristics.

In another embodiment, the third surface 7a of the second substrate 7 may be roughened by, for example, blasting. The roughened third surface 7a has a larger surface area and dissipates heat outside more easily. The roughened third surface 7a also reflects external light in a diffuse manner. The display device thus emits image light with less interference with reflected external light, thus improving the image quality.

In another embodiment, the display device 1 may include multiple transparent members 11. The transparent members 11 are located in the through-holes 8 and seal the light emitters 2. The transparent members 11 may be in contact with the surfaces of the light emitters 2 and in contact with the inner peripheral surfaces 8a of the through-holes 8. The transparent members 11 are made of, for example, a transparent resin material. Examples of the transparent resin material used for the transparent members 11 include a fluororesin, a silicone resin, an acrylic resin, a polycarbonate resin, a polymethyl methacrylate resin, and a polyethylene terephthalate resin.

The through-holes 8 filled with the transparent members 11 reduce thermal resistance on the heat dissipation paths (or the heat transfer paths) from the light emitters 2 to the second substrate 7, as compared with the through-holes 8 filled with gas such as air. The display device 1 thus effectively dissipates heat from the light emitters 2 outside through the second substrate 7. In the present variation, the display device 1 effectively allows the light emitters 2 to have the emission efficiencies less susceptible to their heat, and thus displays high-intensity images.

The display device 1 with the transparent members 11 reduces the likelihood of the light emitters 2 being displaced or being separate from the element mounts after a long period of use. In the present embodiment, the display device 1 has higher long-term stability of the display quality and higher long-term reliability.

For the display device 1 to display full-color images, the pixels in the cavities 3a containing the light emitters 2 include three types of subpixels, or specifically, subpixels for emitting red light, subpixels for emitting green light, and subpixels for emitting blue light. The subpixels for emitting red light (emission wavelength of about 660 nm) may include a red light emitter such as a red LED. The subpixels for emitting green light (emission wavelength of about 520 nm) may include a green light emitter such as a green LED. The subpixels for emitting blue light (emission wavelength of about 450 nm) may include a blue light emitter such as a blue LED. The display device 1 displays full-color images with high definition display quality and reduced deterioration of the viewing angle characteristics and the light intensity characteristics as described above.

In another embodiment of the present disclosure, the structure may include blue LEDs located in all of the cavities 3a as the light emitters 2, and color converters such as phosphors with a thickness in the range of 5 to 30 μm placed by inkjet printing between the bottom surfaces 6 of the cavities 3a and the transparent members 11 to convert blue light into red light or green light. In another embodiment, the structure may include, for example, a color filter layer with a thickness in the range of 1 to 3 μm between the color converters and the transparent members 11 to block, for example, blue excitation light not converted by the color converters.

Red light emitters 2R may include light-emitting portions made of a material such as aluminum gallium arsenide (AlGaAs), gallium arsenide phosphide (GaAsP), gallium phosphide (GaP), or a perovskite semiconductor. Green light emitters 2G may include light-emitting portions made of a material such as indium gallium nitride (InGaN), gallium nitride (GaN), aluminum gallium nitride (AlGaN), gallium phosphide (GaP), zinc selenide (ZnSe), aluminum gallium indium phosphide (AlGaInP), or a perovskite semiconductor. Blue light emitters 2B may include light-emitting portions made of a material such as indium gallium nitride (InGaN), gallium nitride (GaN), aluminum gallium nitride (AlGaN), or zinc selenide (ZnSe).

In one or more embodiments of the present disclosure, the display device 1 can be used in various electronic devices. Such electronic devices include automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

In one or more embodiments of the present disclosure, the display device may include the light emitters located in the respective cavities and displaced from the predetermined arrangement positions P1 on the bottom surfaces of the cavities, and the average of displacements ΔPn is less than or equal to a predetermined value. The cavities (pixels), when viewed collectively, can reduce deterioration of the viewing angle characteristics and the light intensity characteristics. The resultant display device can have high display quality.

In one or more embodiments of the present disclosure, the display device may include the light emitters located in the respective cavities and displaced from the predetermined arrangement positions P1 on the bottom surfaces of the cavities. The first displacements ΔPnx have an average with an absolute value less than or equal to the first predetermined value W1 and the second displacements ΔPny have an average with an absolute value less than or equal to the second predetermined value W2. The displacements of the light emitters can collectively be offset substantially. The pixels (cavities), when viewed collectively, can reduce deterioration of the viewing angle characteristics and the light intensity characteristics. The resultant display device can have high display quality.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### REFERENCE SIGNS

1 display device
2 light emitter
3 cavity member
3a cavity
4 display surface
5 first substrate
5a first surface
5b second surface
6 bottom surface
7 second substrate
7a third surface
7b fourth surface
8 through-hole
8a inner peripheral surface
11 transparent member

1. A display device, comprising:
a cavity member including a display surface and a plurality of cavities in the display surface; and
a plurality of light emitters each located in a corresponding cavity of the plurality of cavities,
wherein when each of the plurality of light emitters has a displacement ΔPn of a reference position P2 from a predetermined arrangement position P1 on a bottom surface of the corresponding cavity of the plurality of cavities, where n is an integer greater than or equal to 2 and ΔPn is a scalar quantity, the displacement ΔPn has an average less than or equal to a predetermined value.

2. The display device according to claim 1, wherein
the displacement ΔPn is less than or equal to a half of a distance from the predetermined arrangement position P1 to an edge of the bottom surface of the corresponding cavity.

3. The display device according to claim 1, wherein
the predetermined value is less than or equal to ⅕ of a distance from the predetermined arrangement position P1 to an edge of the bottom surface of the corresponding cavity.

4. The display device according to claim 1, wherein
the plurality of cavities includes two cavities adjacent to each other, a light emitter located in one of the two cavities is displaced in a first direction, a light emitter located in another of the two cavities is displaced in a second direction, and the first direction and the second direction are substantially opposite to each other.

5. The display device according to claim 4, wherein
an angle between the first direction and the second direction is greater than 90° and less than or equal to 180°.

6. The display device according to claim 1, wherein
the plurality of cavities is in a matrix, and
an average direction of displacement of light emitters located in a first plurality of cavities of the plurality of cavities in a first row is a first row average direction, an average direction of displacement of light emitters located in a second plurality of cavities of the plurality of cavities in a second row adjacent to the first row is a second row average direction, and the first row average direction and the second row average direction are substantially opposite to each other.

7. The display device according to claim 1, wherein
the plurality of cavities is in a matrix, and
an average direction of displacement of light emitters located in a first plurality of cavities of the plurality of cavities in a first column is a first column average direction, an average direction of displacement of light emitters located in a second plurality of cavities of the plurality of cavities in a second column adjacent to the first column is a second column average direction, and the first column average direction and the second column average direction are substantially opposite to each other.

8. A display device, comprising:
a cavity member including a display surface and a plurality of cavities in the display surface; and
a plurality of light emitters each located in a corresponding cavity of the plurality of cavities,
wherein when each of the plurality of light emitters has a displacement ΔPn of a reference position P2 from a predetermined arrangement position P1 on a bottom surface of the corresponding cavity of the plurality of cavities, where P1 is an origin in an orthogonal xy coordinate system and n is an integer greater than or equal to 2, and the displacement ΔPn is divided into a first displacement ΔPnx and a second displacement ΔPny, where ΔPnx and ΔPny are vector quantities, the first displacement ΔPnx is a displacement of the reference position P2 in x-direction from the predetermined arrangement position P1, and the second displacement ΔPny is a displacement of the reference position P2 in y-direction from the predetermined arrangement position P1,
the first displacement ΔPnx has an average with an absolute value less than or equal to a first predetermined value W1, and the second displacement ΔPny has an average with an absolute value less than or equal to a second predetermined value W2.

9. The display device according to claim 8, wherein
the first predetermined value W1 is less than or equal to a half of a distance from the predetermined arrangement position P1 to an edge of the bottom surface of the corresponding cavity in the x-direction, and
the second predetermined value W2 is less than or equal to a half of a distance from the predetermined arrangement position P1 to an edge of the bottom surface of the corresponding cavity in the y-direction.

10. The display device according to claim 8, wherein
the plurality of cavities includes two cavities adjacent to each other, a light emitter located in one of the two cavities is displaced in a first direction, a light emitter located in another of the two cavities is displaced in a second direction, and the first direction and the second direction are substantially opposite to each other.

11. The display device according to claim 10, wherein
an angle between the first direction and the second direction is greater than 90° and less than or equal to 180°.

12. The display device according to claim 8, wherein
the plurality of cavities is in a matrix, and
an average direction of displacement of light emitters located in a first plurality of cavities of the plurality of cavities in a first row is a first row average direction, an average direction of displacement of light emitters located in a second plurality of cavities of the plurality of cavities in a second row adjacent to the first row is a second row average direction, and the first row average direction and the second row average direction are substantially opposite to each other.

13. The display device according to claim 8, wherein
the plurality of cavities is in a matrix, and
an average direction of displacement of light emitters located in a first plurality of cavities of the plurality of cavities in a first column is a first column average direction, an average direction of displacement of light emitters located in a second plurality of cavities of the plurality of cavities in a second column adjacent to the first column is a second column average direction, and the first column average direction and the second column average direction are substantially opposite to each other.

14. The display device according to claim 8, wherein
each cavity of the plurality of cavities has a depth to reflect a half or more of light emitted from a corresponding light emitter of the plurality of light emitters a plurality of times off an inner peripheral surface of the each cavity.

15. The display device according to claim 8, wherein
each cavity of the plurality of cavities has a depth to reflect light with maximum intensity emitted from a corresponding light emitter of the plurality of light emitters a plurality of times off an inner peripheral surface of the each cavity.

16. The display device according to claim 14, wherein
each cavity of the plurality of cavities has a depth being three times or more a height of the corresponding light emitter of the plurality of light emitters.

17. The display device according to claim 8, wherein
each cavity of the plurality of cavities includes an opening in the display surface that is larger than an opening in the bottom surface.

18. The display device according to claim 8, wherein
each cavity of the plurality of cavities has a light-reflective inner peripheral surface.
